(19) United States
(12) Patent Application Publication
(10) Pub. No.: US 2020/0395283 A1
(43) Pub. Date: Dec. 17, 2020

(54) RETURN PATH CAVITY FOR SINGLE ENDED SIGNAL VIA

(71) Applicant: WESTERN DIGITAL TECHNOLOGIES, INC., San Jose, CA (US)

(72) Inventor: Vinod Arjun Huddar, Bangalore (IN)

(73) Assignee: WESTERN DIGITAL TECHNOLOGIES, INC., San Jose, CA (US)

(21) Appl. No.: 16/443,329

(22) Filed: Jun. 17, 2019

(51) Int. Cl. H01L 23/498; H01L 21/48; H01L 25/065; H01L 25/00

(52) U.S. Cl. CPC H01L 23/49827; H01L 23/49838; H01L 21/486; H01L 2225/06562; H01L 25/50; H01L 2225/06506; H01L 2225/0651; H01L 25/0657

(57) ABSTRACT

A substrate largely or entirely devoid of return current vias is disclosed. The substrate may include a first signal layer, a ground plane, a power plane and a second signal layer, each separated by a dielectric material. The ground plane and power plane together form a capacitor providing a return current path for the current in the signal layers.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While many varied packaging configurations are known, flash memory semiconductor devices may in general be fabricated as system-in-a-package (SIP) or multichip modules (MCM), where a plurality of semiconductor die are mounted and interconnected to an upper surface of substrate. The substrate may in general include electrically conductive layers interspersed with dielectric layers. The various conductive layers may for example form a pair of signal layers, a ground plane and a power plane.

In order to transfer current to and from select ones of the signal layers, ground plane and power plane, vias are provided generally orthogonally to the conductive layers. The vias are plated or filled with an electrical conductor to electrically connect select ones of the signal layers, ground plane and power plane to external pins of the semiconductor device.

Traditionally, each signal via also includes a return via to provide a closed loop for the travel of current. The return via placement decides the impedance of signal via as total loop inductance is defined by placement of signal via and return via. It is difficult to provide a return via for every signal via due to space constraints in the substrate, especially in dense substrates like those used in solid state drives. This practical limitation can be especially detrimental when other high speed interfaces have vias passing through planes or referring to the planes for their return.

### DESCRIPTION OF THE DRAWINGS

FIG. 1 is a flowchart for forming a semiconductor device according to embodiments of the present technology.

FIG. 2 is a side view of a first portion of a substrate including a first signal layer, a ground plane and a dielectric layer between the first signal layer and ground plane according to embodiments of the present technology.

FIG. 3 is a top view of a first signal layer of a substrate according to embodiments of the present technology.

FIG. 4 is a bottom view of a ground plane layer of a substrate according to embodiments of the present technology.

FIG. 5 is a side view of a second portion of a substrate including a second signal layer, a power plane and a dielectric layer between the second signal layer and power plane according to embodiments of the present technology.

FIG. 6 is a top view of a power plane layer of a substrate according to embodiments of the present technology.

FIG. 7 is a bottom view of a second signal layer of a substrate according to embodiments of the present technology.

FIG. 8 is a side view of a substrate according to embodiments of the present technology.

FIG. 9 is a side view of a substrate including vias according to embodiments of the present technology.

FIG. 10 is a perspective view of a semiconductor device according to embodiments of the present technology.

FIG. 11 is a side view of a semiconductor device according to embodiments of the present technology.

FIG. 12 is a perspective view of the conductive portions of a substrate showing a current flow in a first direction according to embodiments of the present technology.

FIG. 13 is a perspective view of the conductive portions of a substrate showing a current flow in a second direction according to embodiments of the present technology.

FIG. 14 is a schematic representation of the ground and power planes functioning as capacitive plates according to embodiments of the present technology.

FIG. 15 is a graph showing an example of the improved performance of the present technology over a given frequency range relative to a conventional semiconductor device.

### DETAILED DESCRIPTION

The present technology will now be described with reference to the figures, which in embodiments, relate to a substrate largely or entirely devoid of return current vias. The substrate of the present technology may include a first signal layer, a ground plane, a power plane and a second signal layer, each separated by a dielectric material. The ground plane and power plane together form a capacitor, whose properties are controlled by a dielectric core between the ground and power planes. By providing a high capacitance core and specific properties of the ground and power planes, return currents may be generated in the ground plane and power plane using an AC voltage source.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is ±2.5% of a given dimension.

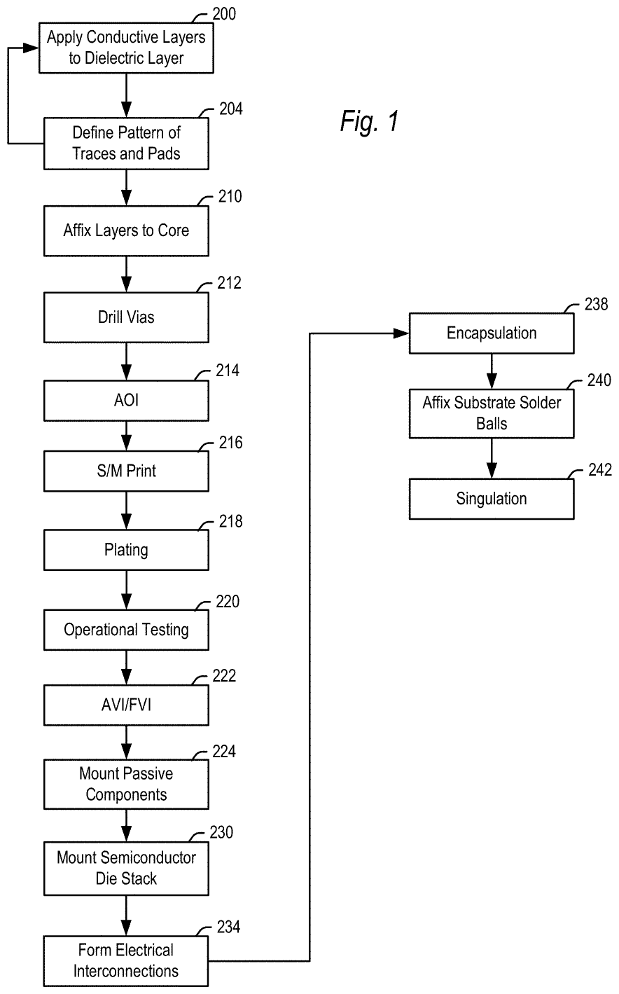

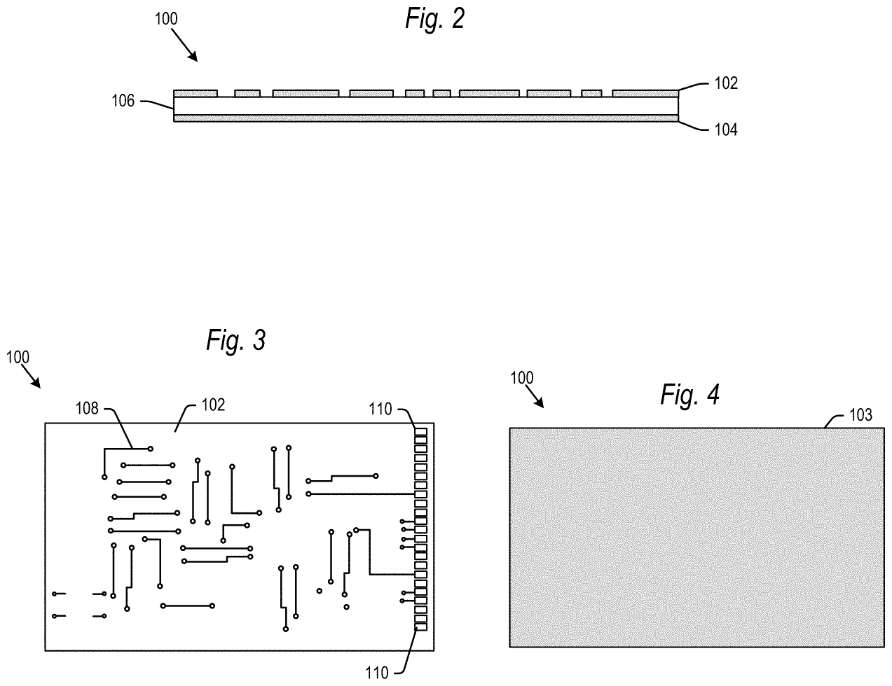

An embodiment of the present technology will now be explained with reference to the flowchart of FIG. 1 and the top, bottom, side and perspective views of FIGS. 2 through 14. Although the figures show an individual semiconductor device 150, or a portion thereof, it is understood that the device 150 may be batch processed along with a plurality of other semiconductor devices on substrate panels to achieve economies of scale. The number of rows and columns of devices 150 on the substrate panels may vary.

The substrate panel for the fabrication of semiconductor device 150 begins with a plurality of substrates 100 (again, one such substrate is shown in FIGS. 2-9). The substrate 100 may be a variety of different chip carrier mediums, including a printed circuit board (PCB), a leadframe or a tape automated bonded (TAB) tape. Where substrate 100 is a PCB, the substrate may be formed of a number of different layers. These layers may include a first signal layer, a ground plane, a power plane and a second signal layer, each such layer being separated by a dielectric. Further details of the layers of substrate 100 will now be explained with reference to FIGS. 2-9.

In embodiments, a signal layer 102 and ground plane layer 104 may be affixed to a first dielectric layer 106 in step 200. The dielectric layer 106 may for example be prepreg, which may be formed of various base materials such as carbon, fiberglass, kevlar, etc. that have been pre-impregnated with a resin such as epoxy to enable adherence of the conductive signal and ground plane layers 102, 104. The dielectric layer 106 may be formed of other materials in further embodiments. The dielectric layer 106 may have a thickness of about 20 μm to 40 μm, although the thickness of the layer 106 may vary outside of that range in alternative embodiments.

The signal and ground plane layers 102, 104 may start as foil layers applied to the dielectric layer 106. The conductive layers 102, 104 may be formed of copper or copper alloys, plated copper or plated copper alloys, Alloy 42 (42Fe/58Ni), copper plated steel, or other metals and materials suitable for use on substrate panels. The conductive layers 104, 105 may have a thickness of about 8 μm to 40 μm although the thickness of the layers may vary outside of that range in alternative embodiments. FIG. 4 shows a bottom view of ground plane layer 104. The ground plane 104 may take up the entire footprint of the substrate 100. In further embodiments, the ground plane 104 may have a size smaller than the overall footprint of the substrate. In such an embodiment, the space not used by the ground plane may be used by electrical traces or it may remain empty.

In step 204, the signal layer 102 may be etched to define a conductance pattern in layer 102 of electrical traces 108 and contact pads 110. FIG. 3 shows an example of a conductance pattern including traces 108 and contact pads 110 formed in signal layer 102 of substrate 100. In embodiments, the pads 110 may include contact pads for receiving wire bonds as explained below. The pattern of traces 108 and contact pads 110 in FIG. 3 by way of example, and the pattern may vary in further embodiments. The conductance pattern in the signal layer 102 may be formed by a variety of known processes, including for example various photolithographic processes.

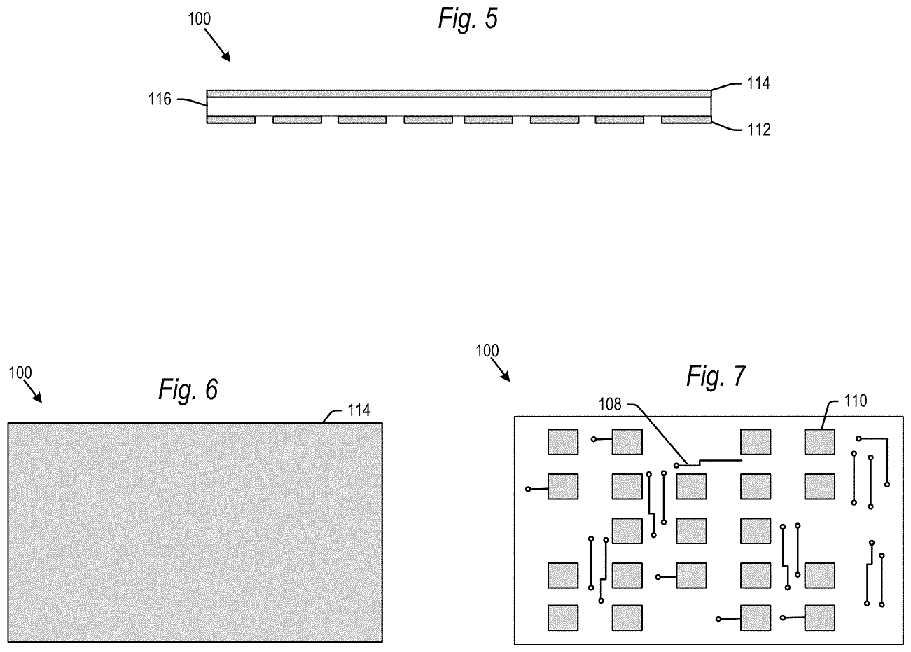

As indicated by the arrow in FIG. 1, steps 200 and 202 may be repeated to form the second signal layer 112 and power plane layer 114 on a second dielectric layer 116 as shown in FIGS. 5-7. The dielectric layer 116 may for example be the same material and the same thickness as dielectric layer 106, such as for example prepreg having a thickness of about 20 μm to 40 μm. The material and thickness of dielectric layer 116 may vary from that described above, and may be the same as, or different from, the dielectric layer 106.

The signal and power plane layers 112, 114 may start as foil layers applied to the dielectric layer 116. The conductive layers 112, 114 may be the same materials, and same thicknesses, as layers 102, 104 described above, though they may be different materials and/or thicknesses, in further embodiments. FIG. 6 shows a top view of power plane 114. The power plane 114 may take up the entire footprint of the substrate 100. In further embodiments, the power plane 114 may have a size smaller than the overall footprint of the substrate. In such an embodiment, the space not used by the power plane may be used by electrical traces or it may remain empty.

In step 204, the signal layer 112 may be etched to define a conductance pattern in layer 112 of electrical traces 108 and contact pads 110. FIG. 7 shows an example of a conductance pattern including traces 108 and contact pads 110 formed in signal layer 112 of substrate 100. In embodiments, the pads 110 may include contact pads for receiving solder balls as explained below. The pattern of traces 108 and contact pads 110 in FIG. 7 by way of example, and the pattern may vary in further embodiments. The conductance pattern in the signal layer 112 may be formed by a variety of known processes, including for example various photolithographic processes.

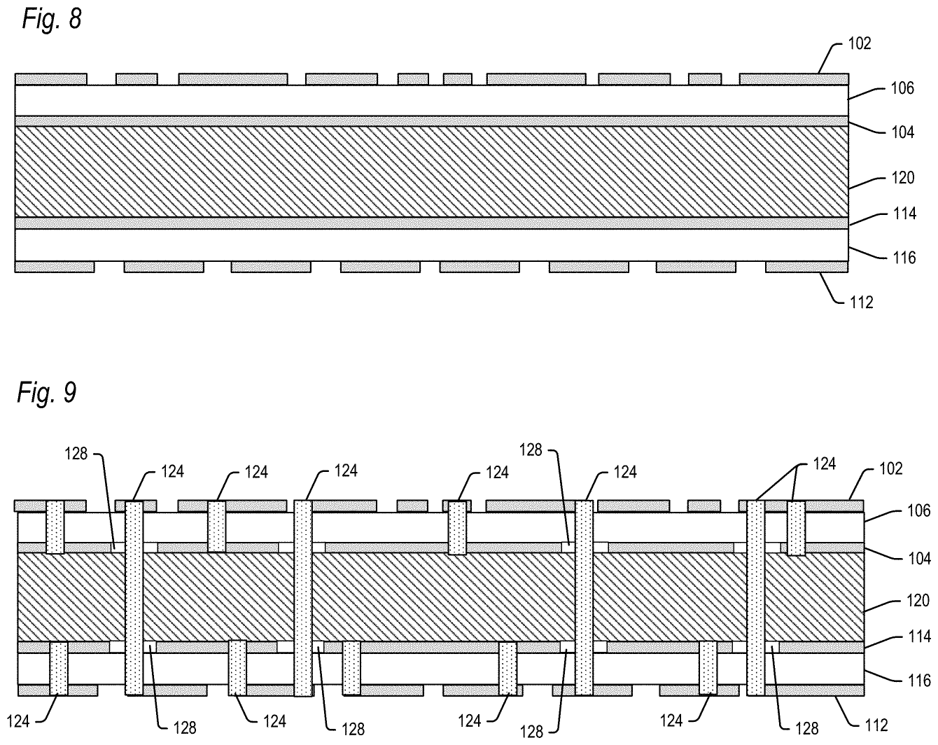

In step 210, the layers 102, 104 and 106 shown in FIGS. 2-4 are affixed to a first surface of a dielectric core, and layers 112, 114 and 116 shown in FIGS. 5-7 are affixed to a second surface of the dielectric core. Such a configuration is shown in FIG. 8. As seen, the first dielectric layer 106 is sandwiched between the first signal layer 102 and the ground plane 104, the second dielectric layer 116 is sandwiched between the second signal layer 112 and the power plane 114, and the dielectric core 120 is sandwiched between the ground plane 104 and power plane 114. The dielectric core 120 may have generally parallel first and second surfaces such that, the ground and power planes 104, 114 form a capacitive unit when current flows through the signal layers 102, 112 as explained hereinafter.

Traditional dielectric cores may formed for example of epoxy resins including FR4 and FR5, bismaleimide triazine (BT), and the like. In accordance with aspects of the present technology, the core 120 has a higher capacitance than traditional dielectric cores. As the dielectric constant, Dₖ, is a factor affecting capacitance, the dielectric constant Dₖ, of core 120 is higher than that of traditional dielectric cores. For example, the dielectric constant, Dₖ, of a traditional FR4 core ranges between 3.6 and 4.3. In accordance with aspects of the present technology, the core 120 is a high dielectric constant material, having a dielectric constant, Dₖ, which may range from 6.0 to 20, and more optimally around 10. It is understood that the dielectric constant may be higher than that in further embodiments. A few examples of a high dielectric constant material for use as core 120 include RO3003 (Dₖ of 6.5), RO3010 (Dₖ of 11.2), RO4360G2 (Dₖ of 6.15), RO3206 (Dₖ of 6.6), RO3210 (Dₖ of 10.8), and RF-10 (Dₖ of 10.2). Each of these materials is manufactured by Rogers Corporation, having offices in Chandler, Ariz., with the exception of RF-10, which is manufactured from Taconic, Inc. of Petersburgh, N.Y. Other materials are possible. It may also be possible to use a traditional material such as FR4 with a modified composition to increase its dielectric constant. For example, providing FR4 with a high glass content and a low resin content may increase the dielectric constant up to about 6.5.

In the embodiments described above, a first assembly is formed including the first signal layer 102, ground plane 104 and dielectric layer 106. A second assembly is formed including the second signal layer 112, power plane 114 and dielectric layer 116. Thereafter, these first and second assemblies are affixed to the dielectric core 120. In further embodiments, a first assembly is formed including the first signal layer 102 and dielectric layer 106. A second assembly is formed including the second signal layer 112 and dielectric layer 116. And a third assembly is formed including the ground plane 104 and power plane 114 affixed to the core 120. Thereafter, the first assembly may be affixed to the ground plane 104 on core 120, and the second assembly to be affixed to the power plane 114 on core 120. Each of the layers 102, 104, 106, 112, 114, 116 and 120 may be affixed to each other in a single process and still further embodiments.

Once the layers of substrate 100 are affixed to each other as described above, vias 124 may be selectively formed through respective layers in step 212 as shown in FIG. 9. It is conceivable that the vias 124 be formed through select layers before all of the layers are assembled together. Vias 124 may be formed by drilling from the top and/or bottom surface of the substrate 100, and then plating or filling the vias with a conductive material such as for example copper, tungsten, gold or alloys thereof. The particular pattern of vias 124 shown in FIG. 9 is by way of example only and may vary in further embodiments.

However, in general, as can be seen, some vias connect traces 108 in the first signal layer 102 with traces 108 in the second signal layer 112. Other vias connect the first signal layer 102 with the ground plane layer 104. Other vias connect the second signal layer 112 with the power plane 114. Still other vias connect the first signal layer 102 to the second signal layer 112.

Of significance to the present technology, the overall number of vias may be reduced in comparison to comparable semiconductor devices of the prior art. In particular, the substrates of traditional semiconductor devices include signal vias and return vias paired with the signal vias. These vias may for example pass between and are coupled to the ground and power planes through the substrate core. However, in accordance with aspects of the present technology, return vias, traditionally running between the ground and power planes, may be omitted. As shown in FIG. 9, anti-vias 128 may be provided around the vias 124 that pass between the ground and power planes to electrically isolate those layers from each other across core 120. Omission of these return vias provides benefits with respect to available space on the substrate, simplified substrate fabrication and reduced overall inductance thereby leading to improved signal integrity. These features and advantages are explained in greater detail below.

Referring again to FIG. 1, the completed substrate 100 may next be inspected in step 214. This step may include an automatic optical inspection (AOI). Once inspected, a solder mask may be applied to the upper and/or lower surfaces of the substrate in step 216. After the solder mask is applied, the contact pads 110, and any other areas to be soldered on the conductance patterns may be plated, for example, with a Ni/Au, Alloy 42, or the like, in step 218 in a known electroplating or thin film deposition process. The substrate 100 may next undergo operational testing in step 220 to ensure the substrate 100 is working properly. In step 222, the substrate may be visually inspected, including for example an automated visual inspection (AVI) and a final visual inspection (FVI) to check for contamination, scratches and discoloration. One or more of these steps may be omitted or performed in a different order in further embodiments.

Assuming the substrate 100 passes inspection, passive components 130 (FIG. 10) may next be affixed to the substrate 100 in a step 224. The one or more passive components may include for example one or more capacitors, resistors and/or inductors, though other components are contemplated. The passive components shown are by way of example only, and the number, type and position may vary in further embodiments.

In embodiments, the present technology may relate to the substrate 100 described above and shown for example in FIG. 10. While an embodiment has been described, it is understood that the substrate 100 may include additional signal, ground and/or power layers, each separated from the next by a dielectric layer.

In further embodiments, the present technology may relate to a semiconductor device 150 formed using the substrate 100 described above. In particular, in step 230, one or more semiconductor die 134 may be mounted on the substrate 100, as shown in the perspective view of FIG. 10. The semiconductor die 134 may for example be memory die such as 2D NAND flash memory or 3D BiCS (Bit Cost Scaling), V-NAND or other 3D flash memory, but other types of die 134 may be used. These other types of semiconductor die include but are not limited to controller die such as an ASIC, or RAM such as an SDRAM, DDR SDRAM, LPDDR and GDDR.

Where multiple semiconductor die 134 are included, the semiconductor die 134 may be stacked atop each other in an offset stepped configuration to form a die stack as shown for example in FIG. 10. The number of die 134 shown in the stack is by way of example only, and embodiments may include different numbers of semiconductor die, including for example 1, 2, 4, 8, 16, 32 or 64 die. There may be other numbers of die in further embodiments. The die may be affixed to the substrate and/or each other using a die attach film.

In step 234, the semiconductor die 134 may be electrically interconnected to each other and to the substrate 100. FIG. 10 shows a perspective view of wire bonds 138 being formed between corresponding die bond pads on respective die 134 down the stack, and then bonded to contact pads 110 on signal layer 102 of substrate 100. The wire bonds may be formed by a ball-bonding technique, but other wire bonding techniques are possible. The semiconductor die 134 may be electrically interconnected to each other and the substrate 100 by other methods in further embodiments, including by through-silicon vias (TSVs) or flip-chip bonding.

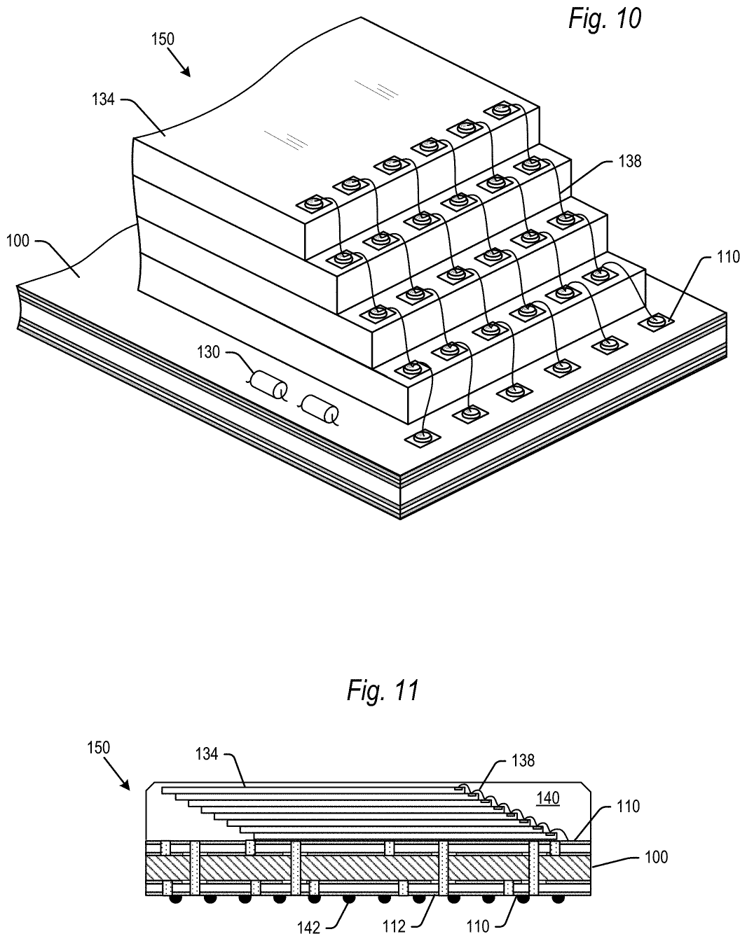

Following electrical connection of the die 134 to the substrate 100, the semiconductor device 150 may be encapsulated in a mold compound 140 in a step 238 and as shown in FIG. 11. Mold compound 140 may include for example solid epoxy resin, Phenol resin, fused silica, crystalline silica, carbon black and/or metal hydroxide. Other mold compounds from other manufacturers are contemplated. The mold compound may be applied by various known processes, including by compression molding, FFT (flow free thin) molding, transfer molding or injection molding techniques.

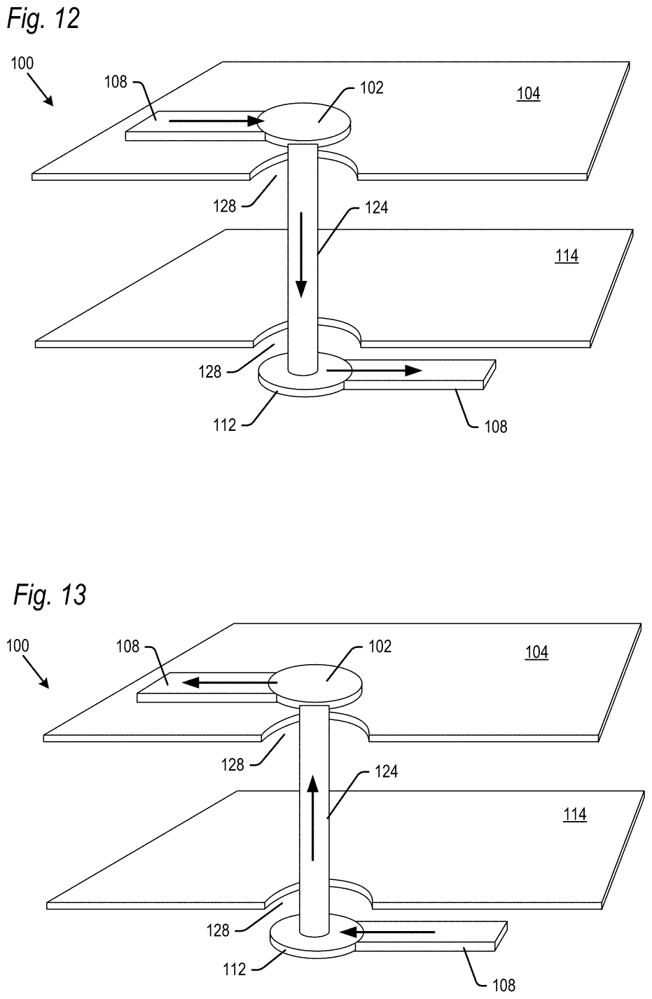

In step 240, solder balls 142 may optionally be affixed to the contact pads 110 on the second signal layer 112 of substrate 100 as shown in FIG. 11. The solder balls 142 may be used to solder the semiconductor device to a host device, such as a printed circuit board. The pattern of contact pads 110 and solder balls 132 shown on the second signal layer 112 of substrate 100 in FIG. 12 is by way of example only, and may vary in further embodiments.

As noted above, the semiconductor device 150 may be formed on a panel of substrates. After formation and encapsulation of the substrates 100, the substrates 100 may be singulated from each other in step 242 to form a finished semiconductor device 150 as shown in FIG. 11. The semiconductor devices 150 may be singulated by any of a variety of cutting methods including sawing, water jet cutting, laser cutting, water guided laser cutting, dry media cutting, and diamond coating wire cutting. While straight line cuts will define generally rectangular or square shaped semiconductor devices 150, it is understood that semiconductor device 150 may have shapes other than rectangular and square in further embodiments of the present technology.

FIGS. 12 and 13 each illustrate the conductive layers 102, 104, 112 and 114 of substrate 100 with the dielectric layers omitted for clarity. In FIG. 12, current is traveling from a semiconductor die 134 along trace 108 in signal layer 102. The current is communicated from signal layer 1022 signal layer 112 by the vias 124, bypassing the ground and power planes by the anti-vias 128. Once in the signal layer 112, the current may travel along trace 108 and out of substrate 100, for example via solder balls 142. In FIG. 13, the current has reversed direction, traveling from signal layer 112 to signal layer 102 along the via 124, bypassing the ground and power planes by the anti-vias 128.

In FIG. 12, the signal current travels from the first signal layer 102 to second signal layer 114 through the via 128. Likewise, in FIG. 13, the signal current travels from the second signal layer 112 to the first signal layer 102 through the via 128. In FIGS. 12 and 13, the first signal layer 102 is coupled to the ground plane 104 by vias 128 (not shown in FIG. 12, shown in FIG. 9). Thus, the ground plane 104 is able to function as a return path for the first signal layer 102. Likewise, the second signal layer 112 is coupled to the power plane 114 by vias 128 (not shown in FIG. 12, shown in FIG. 9). In accordance with the present technology, vias are omitted between the ground and power planes across the core 120, and there is no current flow path between the ground and power planes.

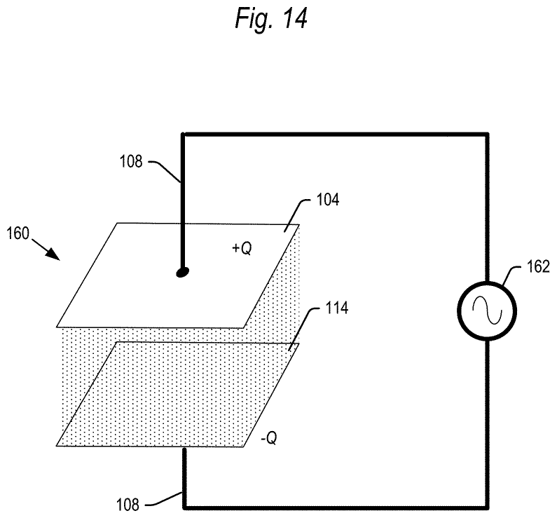

However, the power and ground planes 104, 114, spaced apart by core 120, form a capacitor 160, as modeled in FIG. 14. The capacitor 160 is capable of storing a charge, Q, and, with an alternating current source 162, discharging displacement current to create a return path for the current in both signal layers 102 and 112. In accordance with aspects of the present technology, the properties of core 120 may be controlled to enable the power and ground planes 104, 114 to function as return paths without return vias. For example, by providing the core 120 with a high dielectric constant, Dₖ, the capacitance, C, of capacitor 160 formed by the ground and power planes 104, 114 may be increased, as C is directly proportional Dₖ by:

C=Dₖ*A/d,

where A is area of ground and power planes 104, 114 and d is spacing between the plates. As noted above, the area of the ground and power planes may be the area of the substrate 100, which may vary in embodiments, but may for example be ?? [area?].

The more the capacitance, less is the impedance, X_{c}, of the capacitor 160, as:

Xc=1/(2*3.142*Cf*),

where f is frequency of the current signal in the semiconductor device 150, and C is capacitance of capacitor 160.

Given the low impedance of capacitor 160, the return currents now become displacement current when they move across the capacitor 160, from the ground plane to the power plane or vice-versa. Since the impedance is small between the ground and power planes, the return path loop inductance is also very small, as there is no restriction of the distance of return via from the signal via, as is otherwise the case in a traditional approach of including a return via at some distance from the signal via.

In embodiments, the impedance of capacitor 160 may be defined based on frequency of signal through semiconductor device 150, i.e., based on type of memory interface such as DDR4 RAM or flash memory, etc. Moreover, this approach results in hybrid stack up, in that the dielectric constant of core 120 will be different from (e.g., higher than) the dielectric constant of the dielectric layer 106, 116 between the first signal layer 102 and ground plane 104, and between the second signal layer 112 and the power plane 114.

In embodiments described above, the ground plane 104 is shown associated with the first signal layer 102, and the power plane 114 is shown associated with the second signal layer 112. In further embodiments, the ground plane 104 may be associated with the second signal layer 112, and the power plane 114 may be associated with the first signal layer 102.

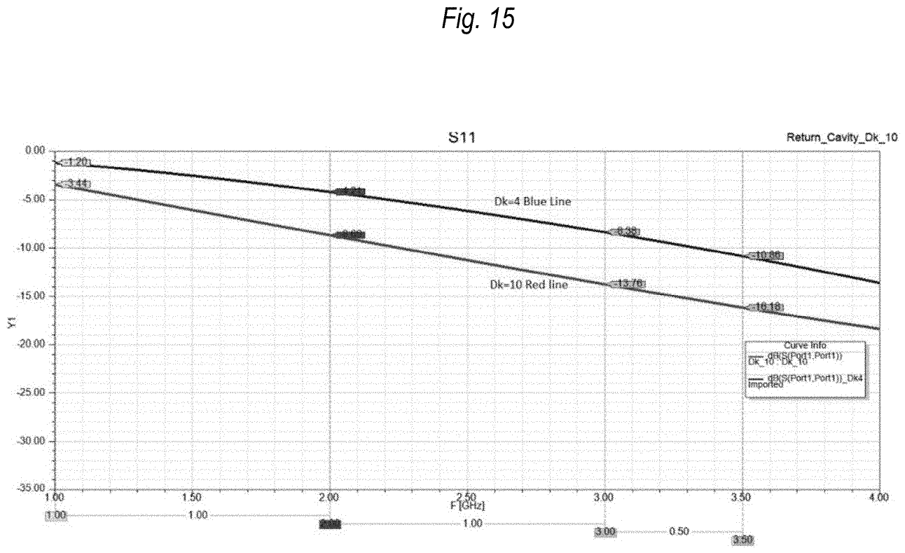

FIG. 15 is a graph showing an example of the improved performance of the present technology over a given frequency range relative to a conventional semiconductor device using a low Dₖ material such as FR4. In this example, the substrate may be as shown in FIG. 9, including a four layer substrate which is 0.2 inches long, 0.1 inches wide and 63 mils thick. As can be seen, return loss has a 6 dB improvement for such small dimension board with Dₖ changing from 4 to 10 for the core 120. As shown, the present technology provides smaller inductive/impedance return path for currents as forward path is fixed with signal via.

In summary, in one example, the present technology relates to a substrate, comprising: first and second signal layers, first and second dielectric layers, a ground plane, a power plane, a dielectric core, wherein the first dielectric layer is sandwiched between the first signal layer and the ground plane, the second dielectric layer is sandwiched between the second signal layer and the power plane, and the dielectric core is sandwiched between the ground plane and power plane; and vias electrically coupling: the first and second signal layers, the first signal layer and the ground plane, the second signal layer and the power plane, but not the ground plane and power plane.

In another example, the present technology relates to a semiconductor device, comprising: a substrate, comprising: first and second signal layers, first and second dielectric layers, a ground plane, a power plane, a dielectric core, wherein the first dielectric layer is sandwiched between the first signal layer and the ground plane, the second dielectric layer is sandwiched between the second signal layer and the power plane, and the dielectric core is sandwiched between the ground plane and power plane, and vias electrically coupling: the first and second signal layers, the first signal layer and the ground plane, the second signal layer and the power plane, but not the ground plane and power plane; and at least one semiconductor die electrically coupled to the substrate.

In a further example, the present technology relates to a semiconductor device, comprising: at least one semiconductor die, a substrate to which the at least one semiconductor die is physically and electrically coupled, the substrate comprising: first and second signal layers, first and second dielectric layers, a ground plane, a power plane, a dielectric core having a dielectric constant of between 6.0 and 20, wherein the first dielectric layer is sandwiched between the first signal layer and the ground plane, the second dielectric layer is sandwiched between the second signal layer and the power plane, and the dielectric core is sandwiched between the ground plane and power plane, and vias electrically coupling: the first and second signal layers, the first signal layer and the ground plane, the second signal layer and the power plane, but not the ground plane and power plane, such that the ground plane and power plane form a capacitor configured to generate a displacement current used as a return path for current flowing between the first and second signal layers through the vias.

In another example, the present technology relates to a substrate, comprising: first and second signal layer means for conducting signals, first and second dielectric layer means for electrical insulation, ground plane means for providing a path to ground, power plane means for providing a power current, dielectric core means for generating a capacitance between the ground and power planes, wherein the first dielectric layer means is sandwiched between the first signal layer means and the ground plane means, the second dielectric layer means is sandwiched between the second signal layer means and the power plane means, and the dielectric core means is sandwiched between the ground plane means and power plane means; and vias means for electrically coupling: the first and second signal layers, the first signal layer and the ground plane, the second signal layer and the power plane, but not the ground plane and power plane.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A substrate, comprising:
first and second signal layers,
first and second dielectric layers,
a ground plane,
a power plane,
a dielectric core, wherein the first dielectric layer is sandwiched between the first signal layer and the ground plane, the second dielectric layer is sandwiched between the second signal layer and the power plane, and the dielectric core is sandwiched between the ground plane and power plane; and
vias electrically coupling:
the first and second signal layers,
the first signal layer and the ground plane,
the second signal layer and the power plane,
but not the ground plane and power plane.

2. The substrate of claim 1, wherein the ground and power planes comprise a capacitor configured to generate a displacement current used as a return path for current flowing between the layers and the ground and power planes through the vias.

3. The substrate of claim 1, wherein the dielectric core has a dielectric constant of between 6.0 and 20.

4. The substrate of claim 1, wherein the dielectric core has a dielectric constant of between 10 and 20.

5. The substrate of claim 1, wherein the first signal layer comprises a conductance pattern comprising electrically conductive traces and electrically conductive contact pads configured to receive an electrical connector to a semiconductor die.

6. The substrate of claim 1, wherein the first signal layer comprises a conductance pattern comprising electrically conductive traces and electrically conductive contact pads configured to receive an electrical connector to a semiconductor die.

7. The substrate of claim 1, wherein at least one of the ground plane and power plane have an area equal to an area of the substrate.

8. A semiconductor device, comprising:
a substrate, comprising:
first and second signal layers,
first and second dielectric layers,
a ground plane,
a power plane,
a dielectric core, wherein the first dielectric layer is sandwiched between the first signal layer and the ground plane, the second dielectric layer is sandwiched between the second signal layer and the power plane, and the dielectric core is sandwiched between the ground plane and power plane, and
vias electrically coupling:
the first and second signal layers,
the first signal layer and the ground plane,
the second signal layer and the power plane,
but not the ground plane and power plane; and
at least one semiconductor die electrically coupled to the substrate.

9. The semiconductor device of claim 8, wherein the ground and power planes comprise a capacitor configured to generate a displacement current used as a return path for current flowing between the layers and the ground and power planes through the vias.

10. The semiconductor device of claim 8, wherein the dielectric core has a dielectric constant of between 6.0 and 20.

11. The semiconductor device of claim 8, wherein the dielectric core has a dielectric constant of between 10 and 20.

12. The semiconductor device of claim 8, wherein the first signal layer comprises a conductance pattern comprising electrically conductive traces and electrically conductive contact pads configured to receive an electrical connector to a semiconductor die.

13. The semiconductor device of claim 8, wherein the first signal layer comprises a conductance pattern comprising electrically conductive traces and electrically conductive contact pads configured to receive an electrical connector to the one or more semiconductor die.

14. The semiconductor device of claim 8, wherein at least one of the ground plane and power plane have an area equal to an area of the substrate.

15. A semiconductor device, comprising:
at least one semiconductor die,
a substrate to which the at least one semiconductor die is physically and electrically coupled, the substrate comprising:
first and second signal layers,
first and second dielectric layers,
a ground plane,
a power plane,
a dielectric core having a dielectric constant of between 6.0 and 20, wherein the first dielectric layer is sandwiched between the first signal layer and the ground plane, the second dielectric layer is sandwiched between the second signal layer and the power plane, and the dielectric core is sandwiched between the ground plane and power plane, and
vias electrically coupling:
the first and second signal layers,
the first signal layer and the ground plane,
the second signal layer and the power plane,
but not the ground plane and power plane, such that the ground plane and power plane form a capacitor configured to generate a displacement current used as a return path for current flowing between the first and second signal layers through the vias.

16. The semiconductor device of claim 15, wherein the dielectric core has a dielectric constant of between 10 and 20.

17. The semiconductor device of claim 15, wherein the first signal layer comprises a conductance pattern comprising electrically conductive traces and electrically conductive contact pads configured to receive an electrical connector to a semiconductor die.

18. The semiconductor device of claim 15 wherein the first signal layer comprises a conductance pattern comprising electrically conductive traces and electrically conductive contact pads configured to receive an electrical connector to the one or more semiconductor die.

19. The semiconductor device of claim 15 wherein at least one of the ground plane and power plane have an area equal to an area of the substrate.

20. A substrate, comprising:
first and second signal layer means for conducting signals,
first and second dielectric layer means for electrical insulation,
ground plane means for providing a path to ground,
power plane means for providing a power current,
dielectric core means for generating a capacitance between the ground and power planes, wherein the first dielectric layer means is sandwiched between the first signal layer means and the ground plane means, the second dielectric layer means is sandwiched between the second signal layer means and the power plane means, and the dielectric core means is sandwiched between the ground plane means and power plane means; and
vias means for electrically coupling:
the first and second signal layers,
the first signal layer and the ground plane,
the second signal layer and the power plane,
but not the ground plane and power plane.
